(19) United States
(12) Patent Application Publication
(10) Pub. No.: US 2015/0185291 A1
(43) Pub. Date: Jul. 2, 2015

(54) SWITCHED CAPACITOR BATTERY UNIT MONITORING SYSTEM

(71) Applicant: Elite Power Solutions LLC, Tempe, AZ (US)

(72) Inventors: Yuan Dao, Phoenix, AZ (US); William Jeffrey Schlanger, Flagstaff, AZ (US)

(21) Appl. No.: 14/657,972

(22) Filed: Mar. 13, 2015

Related U.S. Application Data
(63) Continuation-in-part of application No. 13/077,136, filed on Mar. 31, 2011, now Pat. No. 9,000,935.

(51) Int. Cl. G01R 31/36; G01R 1/30

(52) U.S. Cl. CPC G01R 31/3606; G01R 31/3648; G01R 31/3658; G01R 1/30

(57) ABSTRACT

A switched capacitor battery monitoring system enables reliable measurement of the battery voltages of a plurality of batteries in a battery unit with a single microprocessor and or analog-to-digital converter. A battery unit having a plurality of batteries may have a switched capacitor battery monitor configured on each battery. Each switched capacitor battery monitor utilizes a capacitor that is charged to substantially the same voltage level as the battery it is attached to. The capacitor is isolated from the battery by a switch and the voltage level of the capacitor is provided to an analog-to-digital convened to measure the voltage level of said battery. This method enables the individual battery voltage to be measured and therefore does not measure the cumulative voltage of two or more batteries connected in series. This method maintains the measured voltage below a voltage threshold of the analog-to-digital converter and microprocessor.

### CROSS REFERENCE TO RELATED APPLICATIONS

This application is a continuation in part of U.S. patent application Ser. No. 13/077,136, filed on Mar. 31, 2011, entitled Battery Management System and currently pending; the entirety of which is incorporated by reference herein.

### BACKGROUND OF THE INVENTION

1. Field of the Invention

The present invention relates to a switched capacitor battery unit monitoring system.

2. Background

Battery packs comprising a plurality of batteries are monitored to determine the individual battery state of charge. Lithium ion batteries require special controls in many applications as they require monitoring of their state of charge to ensure that they are not operated below a maximum input voltage value and are not over charged. Lithium batteries can be irreversibly damaged if operated below a maximum input voltage value. Lithium batteries may lose their ability to be fully charged if they are operated below a maximum input voltage for too long. A plurality of lithium batteries are required to generate the voltage needed for many applications including electric vehicles, for example, and therefore a plurality of lithium batteries may need to be connected in series. When a plurality of batteries are coupled together, it is important to keep the level of charge of each battery within a range of the other batteries to prevent damage and to get maximum capacity.

As shown in FIG. 1, lithium batteries have a non-linear discharge profile, with a relatively flat discharge region up to about 80% discharged. Therefore, a small change in voltage can mean a large difference in the state of charge, unlike a lead acid battery that has a relatively linear drop in voltage as the battery is discharged. The state of charge of a lead acid battery, and therefore the amount of power remaining in said lead acid battery, is more easily monitored by a battery monitoring system by simply measuring the voltage of the lead acid battery. The amount of power remaining in a lithium battery system is more difficult to monitor and predict however by simply measuring voltage. It is therefore more difficult to determine the available power remaining in a lithium battery unit by simply measuring the voltage.

A resistive voltage divider may be used to measure the voltage of each battery within a battery unit. A resistive voltage divider may be configured to measure the voltage output of each battery and an analog-to-digital converter may be configured with each resistive voltage divider to provide an output signal of the measured voltage. This requires an analog-to-digital converter for each battery and incorporates components that can introduce error in the measurement of the battery voltage, such as the resistors in the resistive voltage divider, in particular. When batteries are configured in series, the voltage increases with each successive battery in the series connection and therefore measuring from a single common ground across a plurality of batteries connected in series will result in a combined battery voltage that may exceed the threshold limit of an analog-to-digital converter. Many analog-to-digital converters, or microprocessor, can only operate over a particular voltage range and cannot be used for voltages above a threshold values, such as 5V, for example. Therefore, the resistive voltage divider method requires an analog-to-digital converter for each battery in the battery pack.

There exists a need for a battery monitoring method that requires only a single analog-to-digital converter for a plurality of batteries connected in series, and for a monitoring method that is reliable and cost effective.

### SUMMARY OF THE INVENTION

The invention is directed to a switched capacitor battery unit monitoring system that incorporates a plurality of capacitors and a plurality of switch chips configured to temporarily isolate a capacitor from connection with the terminals of a battery to measure the voltage level of said battery. The switched capacitor battery unit monitoring system incorporates capacitors and switch chips to relay the voltage of each battery to analog-to-digital converters. Many analog-to-digital converters have a voltage threshold limit. In addition, most battery units comprising batteries connected in series reach a voltage that is well above the threshold limit of the analog-to-digital converter. Configuring capacitors across each battery in a battery unit comprising a plurality of batteries connected in series, limits the voltage of the capacitor to the voltage level of that individual battery. The capacitor can then be temporarily isolated form the battery terminals and will maintain substantially the same voltage as the individual battery it was connected to. The voltage of the capacitor can then be safely converted into a digital signal by an analog-to-digital converter. The voltage of a plurality of batteries connected in series can be reliably measured by sequentially and temporarily isolating capacitors coupled across the discrete batteries and reading the voltages of the capacitors. Any suitable circuit and switches may be used connect and temporarily isolate the capacitors from the batteries. In an exemplary embodiment, a switch chip is used to couple and isolate the capacitor from the battery. A single microprocessor may be configured to relay the digital signals containing the voltage readings of the individual batteries from the one or more analog-to-digital converters to a control device or central computer or controller. This reduces the number of microprocessors required for monitoring a battery unit comprising a plurality of batteries. In addition, the use of a capacitor instead of a resistive voltage divider provides for a more reliable measurement of each battery voltage since capacitors and switch chips are more accurate than resistive voltage dividers which comprise components, resistors for example, that can have a relative large tolerance. These relatively large tolerances will directly impact the measured value of the battery voltage level.

In an exemplary embodiment, a switched capacitor battery unit monitoring system comprises a plurality of switched capacitor monitors, each comprising a capacitor and a switch that electrically couples and isolates the capacitor to the battery terminals. In an exemplary embodiment, the switch in the switch capacitor monitor is a switch chip, such as CD4053. Texas Instruments Inc. This chip has three independent single pole double throw switches. The switches have a normally closed and normally open electrodes or “contacts” and a common electrode. The switch is controlled by a logic input. When the logic input is at a low logic level (0V), the normally closed electrode is connected to the common electrode. When the logic input is raised to 12V, the normally open electrode is connected to the common electrode (the normally closed electrode is therefore not connected). By connecting the capacitor to common electrode on two switches and connecting the normally closed electrodes of the two switches to the battery positive and negative terminals, the capacitor can be charged to the battery voltage. One of the normally open electrodes of one of the switches is connected to microprocessor ground and the normally open electrode of the other switch is connected to the analog-to-digital input of the microprocessor. In this way, when the microprocessor puts 12V on the logic input of the switch, it can disconnect the capacitor from the battery and connect it to the analog-to-digital input of the microprocessor where the voltage upon it can be read. The third switch in the chip can be used to connect a number of temperature sensors to an analog-to-digital input of the microprocessor in the same way as the capacitors

The voltage of the isolated capacitors may be converted by an analog-to-digital converter to produce a digital signal that can be processed by a microprocessor. In an exemplary embodiment, only a single analog-to-digital converter and a single microprocessor is required for a battery unit. Switch capacitor monitors may be coupled to all of the batteries in a battery unit or to batteries in the battery unit that would have an input voltage to one of the terminals above the maximum input voltage of an analog-to-digital converter. A battery unit utilizing a switched capacitor battery unit monitoring system, as described herein, may have any number (N) of batteries connected in series including, but not limited to, two or more, four or more, six or more, ten or more, 20 or more and any range between and including the number of batteries listed. A battery unit utilizing a switched capacitor battery unit monitoring system, as described herein, may have any number of switch capacitor monitors including. N, N−1, N−2, N−3, and the like.

For the purposes of illustrations, an exemplary battery unit comprising four lithium batteries, as generally shown in the circuit diagram in FIG. 3, may comprise only three switch capacitor monitors coupled to the second, third and fourth batteries. The voltage threshold of the analog-to-digital converter is, for example, 5V. The first battery of the battery unit has a an output voltage of 3.3 volts with a 0V reference. Therefore, the voltage of the first battery can be measured directly by an analog-to-digital converter. The second battery in series has an input voltage of 3.3 volts and an output voltage of 6.6, the combined voltages of first and second batteries connected in series. The voltage level of the second battery cannot be measure directly by the analog-to-digital converter since the output voltage is above the threshold of 5V. Therefore, a switch capacitor monitor is coupled across the terminals of the second battery to enable measurement of the second battery voltage level. Each subsequent battery in the battery unit comprises a switch capacitor monitor. The switch chips may be controlled by a microprocessor that commands the switch chip to open and close as required to measure the voltage of the capacitor.

The switched capacitor battery unit monitoring system may be incorporated into a battery management system as described in U.S. patent application Ser. No. 13/077,136, entitled Battery Management System and incorporated herein by reference. A switched capacitor battery unit monitoring system may provide battery voltage data for number of individual batteries to a battery management system, as described herein. A battery unit monitoring module may comprise a switched capacitor battery unit monitoring system as well as a temperature sensor or other battery status sensor.

In an exemplary embodiment, a battery unit is monitored by a battery management system that is coupled to battery unit monitoring modules through any suitable means. The battery management system may be configured in a control housing of the integrated battery control system. Wires may couple the battery management system with the battery unit monitoring modules. In another embodiment, the battery unit monitoring modules communicate battery data wirelessly to the battery management system, as described in any of the embodiments of U.S. patent application Ser. No. 14/657,248, to Elite Power Solutions LLC.; the entirety of which is incorporated by reference herein. The battery management system may be configured to monitor the voltage and/or temperature of each battery in the battery unit. A battery management system can include battery unit monitoring modules for obtaining data about battery units in a battery pack. A computing device can obtain the data by sending a data request to the first monitoring module. The first monitoring module obtains and transmits data about its connected battery unit to the computing device and sends a data request to the second monitoring module. The second monitoring module obtains and transmits data about its connected battery to the computing device and sends a data request to the next monitoring module. Each successive monitoring module performs the same steps until all the monitoring modules have sent data about their connected battery units to the computing device. This daisy-chain communication method allows a computing device to receive data from all of the battery unit monitoring modules with a single data request. The sequence of receipt of the data is correlated by the computing device to the specific battery unit from which is was received. This greatly simplifies monitoring of the individual battery units and reduces can greatly simplify and reduce wiring requirements. Thus, the computing device needs solely a data request port and input data port(s) to obtain the data for a battery pack.

In one aspect, the present disclosure describes a battery management system. The battery management system includes a computing device with an output data request port and an input data port. The battery management system also includes first and second battery unit monitoring modules, each battery unit monitoring module may be coupled to the input data port of the computing device through a single physical connection, or from a single wireless transmitter. In response to a data request from the output data request port of the computing device, the first battery unit monitoring module transmits data of the first battery unit to the input data port of the computing device, and transmits a data request to the second battery unit monitoring module. In response to the data request from the first battery unit monitoring module, the second battery unit monitoring module transmits data of the second battery unit to the input data port of the computing device through a common connection of the first battery unit monitoring module. The computing device can include an analog-to-digital converter that measures a voltage across the first and second battery units. The computing device can include an analog-to-digital converter that measures a current flowing in the first and second battery units.

The first battery unit monitoring module can connect to a first battery unit in a battery pack of an electric vehicle. The battery management system can also include wiring connecting the computing device to the battery unit monitoring modules. Because the battery units in a battery pack can be wired in series, the physical locations of the positive and negative terminals arranged in an alternating fashion, the second battery unit monitoring module is oriented in an opposite direction from the first battery unit monitoring module. The first battery unit monitoring module can include an analog-to-digital converter. The analog-to-digital converter can measure a voltage of the first battery unit. The first battery unit monitoring module can include a temperature monitoring device that measures a temperature of the first battery unit. The temperature can be expressed as a voltage which is applied to an input of the analog-to-digital converter. Data of the first battery unit can be a voltage and a temperature of the first battery unit. Data of the second battery unit can be a voltage and a temperature of the second battery unit.

In an exemplary embodiment, the computing device of the battery management system can automatically initiate collection of data from the battery unit monitoring modules. In one embodiment, a computing device will send a data request to the first battery unit monitoring module after the computing device has not received data on the input data port for a predetermined period of time. Since data is automatically sent sequentially to the input data port from the battery unit monitoring modules until the last battery unit monitoring module sends data, the extended delay in receiving data is a signal to the computing device to re-initiate collection of data. The predetermined period of time may be any suitable amount of time, such as 20 ms, 40 ms, 50 ms, and the like.

The computing device can output an alarm when an error condition is detected. The error condition can be a high voltage condition, a low voltage condition, a high current condition, a high temperature condition, or a connection fault condition. The computing device can shut off a battery charger when the computing device detects a high voltage condition across the first and second battery units. The computing device can shut off a motor controller when the computing device detects a low voltage condition across the first and second battery units. The battery management system can include a monitor, such as a video monitor, that displays the data of the first and second battery units. The battery management system can include a connection fault detector that detects a connection between a node at a zero voltage reference level and the first and second battery units. The battery management system can include one or more battery unit balancing systems, each system balancing charge in a battery unit. A battery management system, as described herein, may comprise a battery balancing system is described in U.S. Pat. No. 8,723,482, entitled Battery Unit Balancing System, to Dr. Yuan Dao, et al.; the entirety of which is incorporated by reference herein.

In another aspect, the present disclosure describes a battery management system with a computing device and first and second battery unit monitoring modules. The computing device includes a first output data request port and an input data port. The first battery unit monitoring module includes a first input data request port connected to the output data request port of the computing device, a first output data port connected to the input data port of the computing device, and a second output data request port. The second battery unit monitoring module includes a second input data request port connected to the second output data request port of the first battery unit monitoring module, and a second output data port connected to the input data port of the computing device.

In another aspect, the present disclosure describes a method of managing a battery. The method includes transmitting, by a computing device, a first data request to a first battery unit monitoring module. The method also includes transmitting, by the first battery unit monitoring module, data of a first battery unit to an input data port of the computing device in response to the first data request. The method also includes transmitting, by the first battery unit monitoring module, a second data request to a second battery unit monitoring module. The method also includes transmitting, by the second battery unit monitoring module, data of a second battery unit to the input data port of the computing device in response to the second data request.

A lithium battery, as used herein, comprises lithium metal or lithium compounds in the anode. Lithium batteries have a very high charge density or long life, and can operate at temperature extremes. The lifetime of a lithium battery may be as much as ten times greater than a lead-acid battery. In addition, lead-acid batteries have a somewhat limited effective operating temperature range. Lithium batteries can produce voltages from 1.5 to 3.7V.

A physical cable may be coupled between the battery monitoring module and the battery data input for the transfer of data and requests. In an alternative embodiment, a wireless transmitter may transmit a request for data or send data, and a wireless receiver may be configured for receipt of this information. A wireless transmission system for receiving battery data from a battery unit monitor module is described in U.S. patent application Ser. No. 14/225,251, filed on Mar. 25, 2014, entitled Uninterrupted Lithium Battery Power Supply System; the entirety of which is incorporated by reference herein. A wireless transmitter may be coupled with the computing device and may send a request for battery monitoring module data. A wireless receiver coupled with a first battery monitoring module may receive this request and may then send data about the first battery and/or battery unit to the battery data input through a wireless transmitter. Again, a wireless signal receiver may be coupled with the battery data input to provide this data to the computing device. Any suitable configuration of wireless receivers and transmitters may be used to reduce the number of physical connections between a battery pack and a power control system. A battery data input may be coupled to a battery monitoring module through a cable or wirelessly. A battery data input may comprise a wireless signal receiver that is configured to receive a wireless signal having battery unit parameter data. A wireless signal generator may be coupled with a battery monitoring module. Likewise a data request output may comprise a wireless signal generator that is received by a wireless signal receiver of a battery monitoring module.

A battery management system, as described herein, comprises a battery data input coupled with said battery monitoring modules, and computing device coupled with a data request output, and the data input. In an exemplary embodiment, a battery management system controls a charging circuit coupled with the batteries or battery units to provide a charging current from said AC power input when a voltage of one of said batteries or battery units drops below a threshold value. A threshold value may be input during instillation by an operator of the system or at the manufacturer prior to delivery and may be stored by the computing device. A threshold value may be 3.2V or more, 3.3V or more, 3.4V or more, 3.5V or more and any value between and including the threshold values provided.

In an exemplary embodiment, a power control system comprises a program to determine the state of charge of a battery unit or battery, or the amount of available charge remaining. The calculation takes into account the battery unit or pack voltage prior to the utilization of battery power as the output power. The program utilizes input related to the power being drawn by the powered device, such as current, voltage and time, and calculates the total power usurped from the battery pack. The program can then calculate the discharge percent of the battery pack, as depicted in FIG. 1. A power control system may calculate the time remaining before the battery pack is discharged 80% and may send an alert via a data transmission system of the remaining time before shut-down. A power control system may shut-down the battery pack if a discharge level of 80% or more is reached, for example, in an effort to protect the system and prevent damage to the battery pack.

The summary of the invention is provided as a general introduction to some of the embodiments of the invention, and is not intended to be limiting. Additional example embodiments including variations and alternative configurations of the invention are provided.

### BRIEF DESCRIPTION OF THE DRAWINGS

The accompanying drawings are included to provide a further understanding of the invention and are incorporated in and constitute a part of this specification, illustrate embodiments of the invention, and together with the description serve to explain the principles of the invention.

FIG. 1 shows an exemplary discharge profile for a lithium battery.

FIG. 2 shows a top-down view of an exemplary battery pack with battery monitoring modules configured thereon.

FIG. 3 shows an exemplary circuit diagram of a switched capacitor battery unit monitoring system.

FIG. 4 shows a block diagram depicting an exemplary embodiment of a battery management system connected to a battery pack.

FIG. 5 shows a block diagram depicting an exemplary arrangement of battery unit monitoring modules of the battery management system with respect to the battery units of the battery pack.

FIG. 6 shows a diagram depicting connections between battery unit monitoring modules.

### DETAILED DESCRIPTION OF THE ILLUSTRATED EMBODIMENTS

Corresponding reference characters indicate corresponding parts throughout the several views of the figures. The figures represent an illustration of some of the embodiments of the present invention and are not to be construed as limiting the scope of the invention in any manner. Further, the figures are not necessarily to scale, some features may be exaggerated to show details of particular components. Therefore, specific structural and functional details disclosed herein are not to be interpreted as limiting, but merely as a representative basis for teaching one skilled in the art to variously employ the present invention.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Also, use of “a” or “an” are employed to describe elements and components described herein. This is done merely for convenience and to give a general sense of the scope of the invention. This description should be read to include one or at least one and the singular also includes the plural unless it is obvious that it is meant otherwise.

In cases where the present specification and a document incorporated by reference include conflicting and/or inconsistent disclosure, the present specification shall control. If two or more documents incorporated by reference include conflicting and/or inconsistent disclosure with respect to each other, then the document having the later effective date shall control.

Certain exemplary embodiments of the present invention are described herein and illustrated in the accompanying figures. The embodiments described are only for purposes of illustrating the present invention and should not be interpreted as limiting the scope of the invention. Other embodiments of the invention, and certain modifications, combinations and improvements of the described embodiments, will occur to those skilled in the art and all such alternate embodiments, combinations, modifications, improvements are within the scope of the present invention.

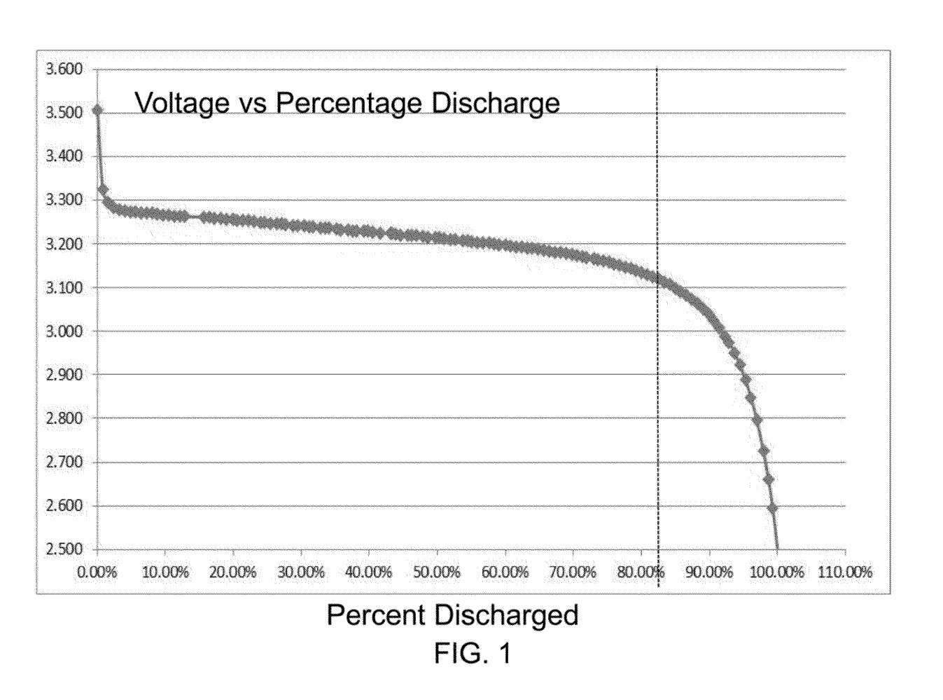

As shown in FIG. 1, a lithium battery has a non-linear discharge profile. The discharge rate from approximately 5% to 80% of full charge is substantially linear but has a very small slope. Therefore, it is difficult to estimate the state of charge of a battery, or battery unit by measuring the voltage. Small variations in voltage may result in erroneous estimates of the state of charge. As described herein, a power control system may calculate the time remaining before a battery pack should be shut down when being used as the output power supply. The power control system and specifically the computing device may initiate battery shut down if a calculated value of 80% discharged or more is reached.

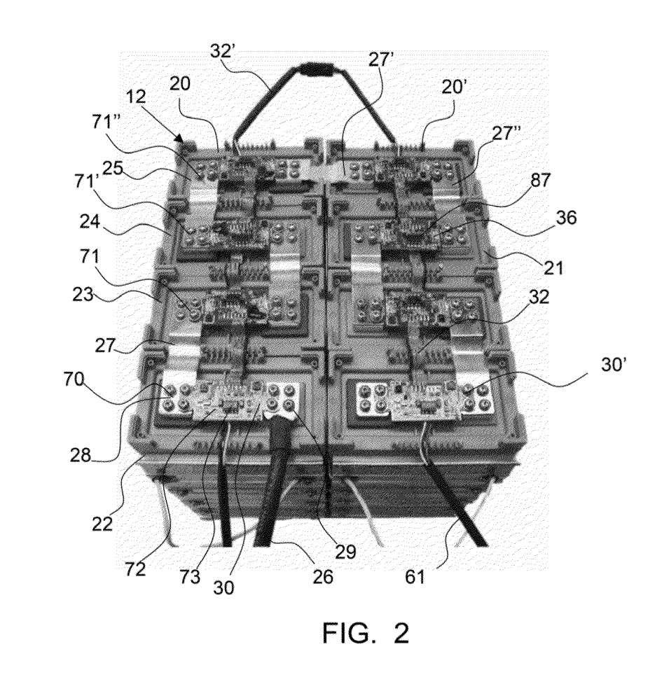

As shown in FIG. 2, an exemplary battery pack 12 comprises two battery units 20 and 20′, each having four individual lithium batteries 21. The first, second, third and fourth batteries 22, 23, 24 and 25, respectively, are connected in series in each battery unit. The batteries are all connected in series by jumpers 27. A jumper 27′ connects the first battery unit 20 with the second battery unit 20′. Battery monitoring module 30 is configured between the positive 28 and negative 29 terminals of the first battery 22 of the first battery unit 20 and comprises a microprocessor 73 and an analog-to-digital converter 72. A temperature sensor 36 may be coupled to each battery or to a battery unit to monitor temperature and provide this information to a battery monitoring module. As shown in FIG. 2, a plurality of switch capacitor battery monitors 71-71″ are configured on the individual batteries 22 to 25. A switch capacitor battery monitors may comprise a circuit 87, a capacitor and a switch chip to determine the voltage state of a battery, as described herein. A single analog-to-digital converter 72 and microprocessor 73 are utilized in the switched capacitor battery unit monitoring system 70 for each battery unit 20, and are configured on the battery monitoring module 30. Connectors 32 connect sensors and/or the switch capacitor battery monitors in a daisy-chain configuration and to the battery monitoring module 30′. A battery power cable 26 is configured to provide power from the battery pack 12. A battery module cable 61 is configured to couple with a battery data input, as shown in FIG. 2.

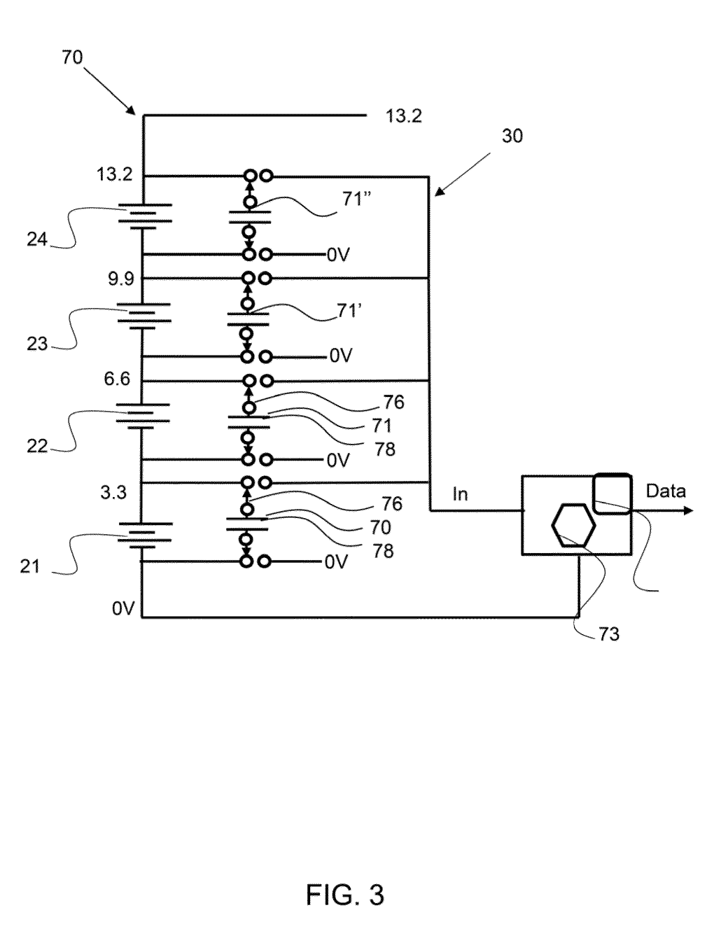

Referring now to FIG. 3, a switched capacitor battery unit monitoring system 70 comprises a plurality of switch capacitor battery monitors 71-71″ coupled to batteries 22, 23 and 24, respectively. Note that the first battery 21 in the series connection does not have a switch capacitor battery monitor as the voltage of the first battery does not exceed the threshold value of the analog-to-digital converter 72. Each switch capacitor battery monitor comprises a capacitor 78 and a switch chip 76, indicated by the round circles. An exemplary switch is a double pole, double throw switch, as is known in the art. The batteries are connected in series, wherein the voltage increases along the series connection from 3.3V after the first battery 21, to 6.6V after the second battery 22, to 9.9V after the third battery 23 and to 13.2V after the fourth battery 24 in the series. Since the switched capacitor battery monitors are configured across the terminals of each battery in the series, the capacitors of the switched capacitor battery monitors are charged only to a voltage level of each individual battery and not the cumulative or series voltage. This enables input from the switched capacitor battery monitors directly to the analog-to-digital converter and/or microprocessor as the voltage is not above an upper maximum input voltage value, or threshold value of 5V, for example. An analog-to-digital converter 72 receives voltage input from each of the switch capacitor battery monitors and converts the voltage reading into a digital signal that is processed by the microprocessor and transmitted to a data input of a battery management system. This exemplary battery unit monitoring module comprises a single microprocessor and a single analog-to-digital converter and reliably measures the voltage of two or more batteries. The microprocessor may control the switch chips in a sequential order to receive individual battery voltage data sequentially. After the microprocessor has received the last input in the series, the microprocessor may restart the opening and closing of switch chips to receive voltage readings for each of the batteries from their respective switch capacitor battery monitors.

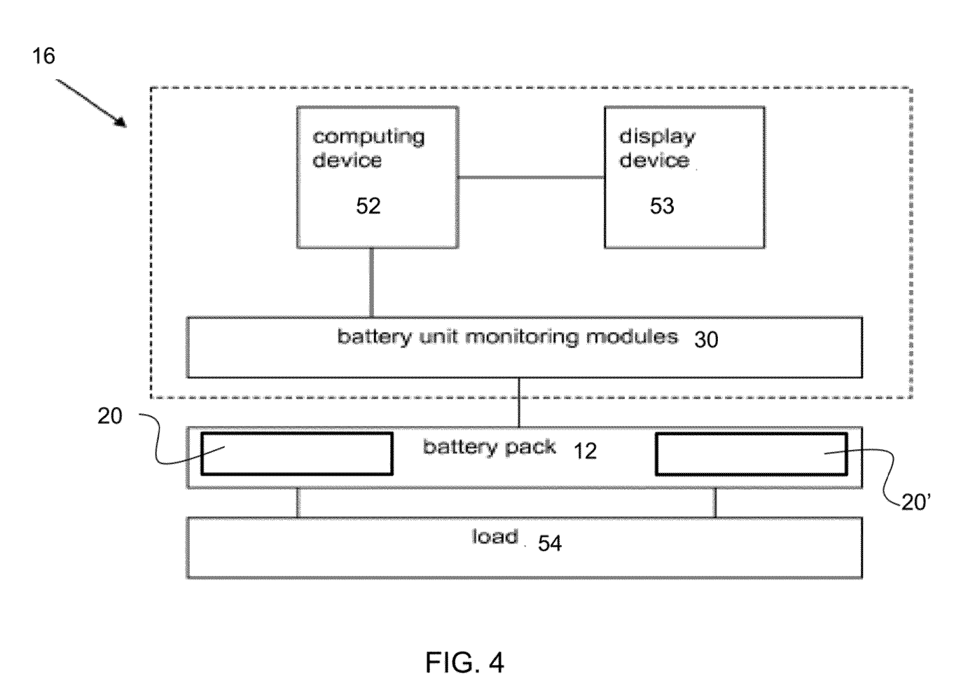

Referring now to FIG. 4, a block diagram of an exemplary embodiment of a battery management system 16 connected to a battery pack 12 is shown. The battery management system includes battery unit monitoring modules 30 (e.g., sense boards), a computing device 52, and a display 53 (e.g. a monitor such as an LCD monitor or a monitor incorporated into another device, such as a DVD player). The computing device 52 may receive voltage and/or current data for the entire battery pack and output the data to the display 53. In various embodiments, the computing device can determine the state of charge of the battery pack 12 by measuring the amount of current that flows in or out of the battery pack. The battery pack can integrate the amount of current to determine the state of charge. In some embodiments, when the battery pack reaches a minimum, predetermined voltage, the computing device can set the pack's state of charge to about 0%. When the batter), pack reaches a maximum, predetermined voltage, the computing device can set the state of charge to about 100%.

In some embodiments, the battery pack 12 may include a plurality of battery units 20 (e.g. battery cells). Each battery unit may include a battery cell or a plurality of battery cells. The battery pack can connect to an external load or powered device 54, such as a motor for an electric vehicle. Each battery unit monitoring modules of the management system can connect to a battery unit. A monitoring module can obtain data, such as voltage and/or temperature, for the battery unit connected to the module. The monitoring modules can transmit the data to the computing device, which can output the data to the display.

In some embodiments, the computing device 52 may be configured to operate with a predetermined, fixed number of battery unit monitoring modules 30. In some embodiments, the computing device may be configured to scan the modules to determine the number of modules present. The computing device can scan the battery unit monitoring modules to determine the number of monitoring modules in the system. For example, in some embodiments, the computing device can output a scan signal to the first monitoring module. In response, the monitoring module can return battery unit voltage and temperature data to the computing device and can output a scan signal to a successive monitoring module. In some embodiments, the monitoring module can also return battery unit voltage and temperature data to the computing device, and can output a scan signal to the next module. Thus, the computing device can count the number of monitoring modules by the number of voltage and temperature data packets received. Further, the computing device can number a monitoring module and/or battery unit based on the module's or unit's position in the order of scan signals received. In some embodiments, a user can configure the computing device to set the number of monitoring modules or to instruct the device to scan the modules and obtain the number of modules itself.

The computing device can detect error conditions for individual battery units and/or the entire battery pack. Exemplary error conditions can include conditions such as high voltage conditions, low voltage conditions, high current conditions, and high temperature condition. Another exemplary error can be a connection fault condition, e.g., a connection between at least one battery unit and a contact point with a zero-voltage reference level, such as a chassis of an electric vehicle.

When an error is detected, the computing device can initiate a measure based on the error condition. For example, if the computing device detects a high voltage condition for the entire battery pack, the computing device can inactivate a device that charges the pack (not shown). In another example, if the computing device detects a first low voltage condition, the computing device 52 can output a low voltage warning to the display. If the battery pack's voltage drops further, triggering a second low voltage condition, the device can inactivate a load connected to the battery pack, such as a motor controller of an electric vehicle.

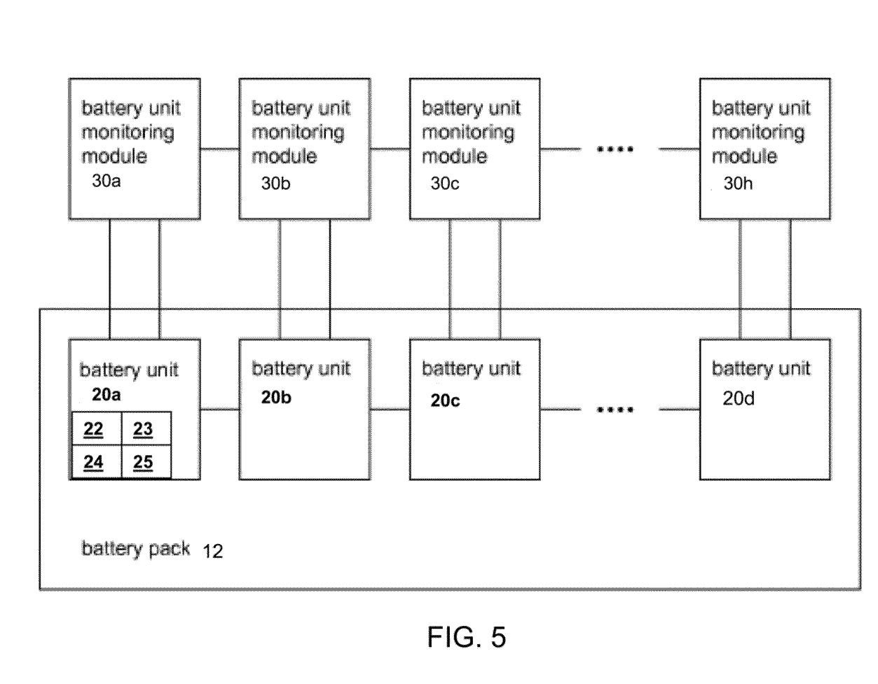

Referring now to FIG. 5, a block diagram of an exemplary arrangement of battery unit monitoring modules 30 and battery units 20 in a pack 12 is shown. In this embodiment, the monitoring modules are connected to the battery units, which are connected in series. Each battery unit may comprise a plurality of individual batteries, 22 to 25, as shown in battery unit 20a, for example. Each monitoring module can be connected to a single battery unit. The battery unit can supply the connected monitoring module with power for performing its operations.

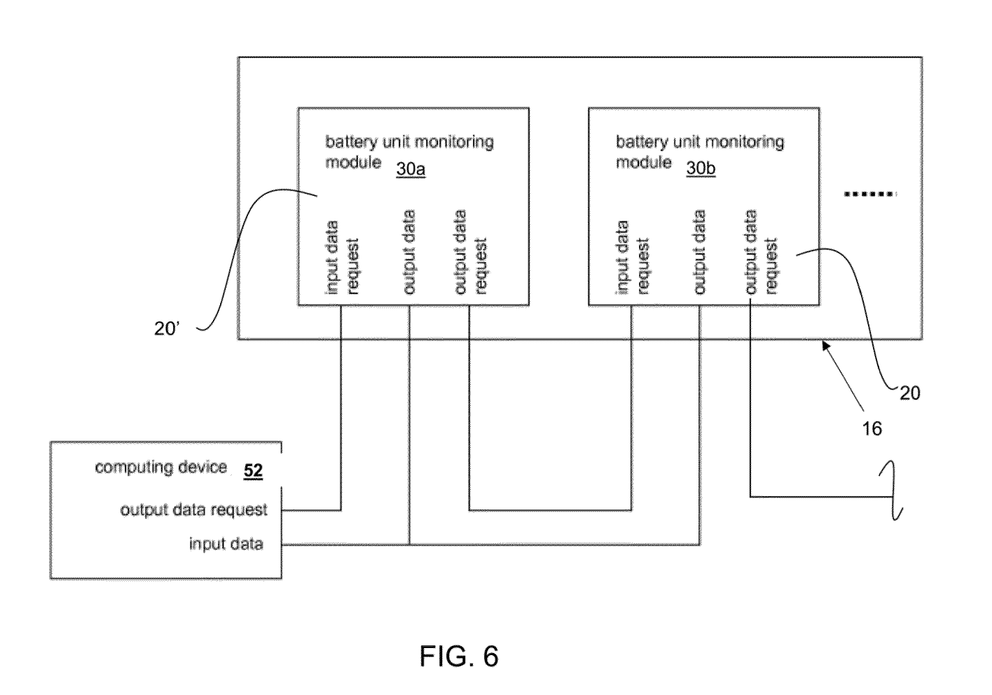

FIG. 6 is a block diagram depicting connections within the battery management system 16 between the computing device 52 and the battery unit monitoring modules 30a and 30b. The computing device includes an output data request port (also referred to herein as an “enable output”) and an input data port. Each monitoring module includes an output data port, an input data request port (also referred to herein as an “enable input”), and an output data request port. Each monitoring module's output data port is connected in parallel to the computing device's input data port.

The computing device's output data request port is connected to the first one of the battery unit monitoring module's 30a input data request port. The first battery unit monitoring module's 30a output data request port is connected to the input data request port of the second battery unit monitoring module 30b. In turn, the second battery unit monitoring module's 30b output data request is connected to the input data request port of the next monitoring module (not shown). The remaining monitoring modules are connected in the same manner. The communications of the computing device 52 and battery unit monitoring modules described herein are transmitted from and received at these ports, as would be understood by one of ordinary skill in the art. Further, in various embodiments, the computing device and monitoring modules include voltage and ground connections such that the computing device can provide power (e.g., 12V) and ground to the monitoring modules.

In operation, to obtain data about the battery units 20, the computing device sends a data request signal (also referred to herein as an “enable signal” or an “enable pulse”) to the first battery unit monitoring module 30a. In response, the monitoring module 30a transmits data about a connected battery unit 20a to the computing device. After the module 30a finishes transmitting data, the module 30a sends a data request signal to the second battery unit monitoring module 30b. In response, the monitoring module 30b transmits data about a connected battery unit 20b to the computing device. After the module 30b finishes transmitting data, the module 30b sends a data request signal to the third battery unit monitoring module 30c, and the process continues for the rest of the monitoring modules.

Using this communication system, the computing device can match data with a battery unit according to the order in which the device receives data. Thus, the first set of data can be matched to the first battery unit 20a, the second set of data to the second unit 20b, and so forth. In this manner, the computing device uses few ports for obtaining data and matching the data to battery units. In some embodiments, such a battery management system may eliminate the needs for dedicated addressing ports, addressing switches, and/or jumpers.

When the computing device does not receive data from a battery unit 195 for at least a predetermined period of time (e.g. 20 ms, although other times may be used), the computing device can conclude that data collection for the battery unit 20 has been completed. The computing device can obtain another set of data by transmitting another data request to the first battery unit monitoring module 30a, thereby restarting the data collection process. In some embodiments, the computing device can collect data about the battery units as often as needed or programmed, e.g., several times per second.

In some embodiments, the computing device can first compare the number of data received with the number of monitoring modules. If the numbers match, the computing device can determine all the monitoring modules are operational and continue obtaining data about the battery units. If the numbers do not match, the computing device can conclude that at least one monitoring module and/or battery unit is not operational. The computing device can generate and output an error message to the display. Since the modules transmit data to the computing device in sequential order, the computing device can identify the non-operational module or unit according to the number of data received. In this manner, the computing device can inform a user of physical locations of faults in the monitoring modules or battery pack, allowing the user to troubleshoot problems.

Regarding the individual monitoring modules, in some embodiments, a module can measure data for a connected battery unit upon receiving a data request signal. In some embodiments, a module can measure and store data in a buffer. Then, when the module receives the data request signal, the module may access the buffer and may transfer the data stored therein to the computing device.

The monitoring module can transmit the data to the computing device in a human readable form. The monitoring modules can transmit the data via an asynchronous serial protocol, such as protocols used for RS-232 or USB connections. The monitoring modules can transmit the data at any rate and with any number of start and/or stop bits. For example, a module can transmit at 9600 Baud with 1 start bit and 1 stop bit.

It will be apparent to those skilled in the art that various modifications, combinations and variations can be made in the present invention without departing from the spirit or scope of the invention. Specific embodiments, features and elements described herein may be modified, and/or combined in any suitable manner. Thus, it is intended that the present invention cover the modifications, combinations and variations of this invention provided they come within the scope of the appended claims and their equivalents.

What is claimed is:

1. A switched capacitor battery unit monitoring system comprising:
a first switch capacitor battery monitor comprising:
a first capacitor coupled across the terminals of a first battery in a battery pack to produce a first capacitor voltage level that is substantially the same as a voltage level of said first battery; and
a first switch;
a second switch capacitor battery monitor comprising:
a second capacitor coupled across the terminals of a second battery in said battery pack to produce a second capacitor voltage level that is substantially the same voltage as a voltage level of said second battery; and
a second switch;
at least one analog-to-digital converter that is electrically coupled with the first and second switched capacitor battery monitors;
a single microprocessor;
wherein the first battery voltage level is measured by opening said first switch and providing the first capacitor voltage level to the analog-to-digital converter;
wherein the second battery voltage level is measured by opening said second switch and providing the second capacitor voltage level to the analog-to-digital converter; and
wherein the microprocessor controls the first and second switches to change an input to the analog-to-digital converter from the first capacitor to the second capacitor.

2. The switched capacitor battery unit monitoring system of claim 1, wherein the first and second switches are switch chips.

3. The switched capacitor battery unit monitoring system of claim 1, wherein the first and second switch capacitor battery monitors each comprises a separate analog-to-digital converter.

4. The switched capacitor battery unit monitoring system of claim 1, wherein the first and second batteries are lithium batteries.

5. The switched capacitor battery unit monitoring system of claim 1, further comprising:
a third switch capacitor battery monitor comprising:
a third capacitor coupled across the terminals of a third battery in said battery pack to produce a third capacitor voltage level that is substantially the same as a voltage level of said third battery; and
a third switch chip;
wherein the third battery voltage level is measured by opening said third switch and providing the third capacitor voltage level to the analog-to-digital converter; and
wherein the microprocessor controls the third switch chip to provide of the third capacitor voltage level to the analog-to-digital converter.

6. A battery management system comprising:
a computing device comprising:
an output data request port; and
an input data port;
wherein the computing device receives battery data from at least one battery unit monitoring module comprising:
first switch capacitor battery monitor comprising:
a first capacitor coupled across the terminals of a first battery in a battery pack to produce a first capacitor voltage level that is substantially the same as a voltage level of said first battery; and
a first switch;
a second switched capacitor battery monitor comprising:
a second capacitor coupled across the terminals of a second battery in said battery pack to produce a second capacitor voltage level that is substantially the same voltage as a voltage level of said second battery; and
a second switch;
at least one analog-to-digital converter that is electrically coupled with the first and second switched capacitor battery monitors;
a single microprocessor;
wherein the first battery voltage level is measured by opening said first switch and providing the first capacitor voltage level to the analog-to-digital converter;
wherein the second battery voltage level is measured by opening said second switch and providing the second capacitor voltage level to the analog-to-digital converter; and
wherein the microprocessor controls the first and second switches to change an input to the analog-to-digital converter from the first capacitor to the second capacitor.

7. The battery management system of claim 6, wherein the first and second switches are switch chips.

8. The battery management system of claim 6, wherein the first and second switch capacitor battery monitors each comprises a separate analog-to-digital converter.

9. The battery management system of claim 6, where in the battery management system comprises:
i. a first battery unit monitoring module coupled with a first battery unit and comprising:
an input data request port connected to the output data request port of the computing device; and
an output data request port;
an output data port connected to the input data port of the computing device; and
ii. a second battery unit monitoring module coupled with a second battery unit and comprising:
a single input data request port connected only to the output data request port of the first battery unit monitoring module, therein defining a module connection between said first battery unit monitoring module and said second battery unit monitoring module; and
an output data port connected to the input data port of the computing device;
wherein the first battery unit monitoring is a master to said second battery unit monitoring module and the second battery unit monitoring module is a slave to the first battery unit monitoring module;
wherein the first battery unit monitoring module responds to a data request signal from the output data request port of the computing device by transmitting data of the first battery unit to the input data port of the computing device and subsequently transmits a data request to the second battery unit monitoring module through said module connection; and
wherein the second battery unit monitoring module responds to the data request from the output data request port the first battery unit monitoring module by transmitting data of the second battery unit to the input data port of the computing device;
wherein the computing device receives data from the first and second battery unit monitoring modules sequentially after sending a single data request signal to only the first battery unit monitoring module; and
wherein the computing device receives data from the second battery unit monitoring module automatically after receiving data from the first battery unit monitoring module.

10. The battery management system of claim 6, comprising at least four lithium batteries connected in series.

11. The battery management system of claim 6, wherein the battery unit monitoring module comprises a temperature monitoring device that measures a temperature of the first and second batteries.

12. The battery management system of claim 6, wherein the computing device transmits a second data request to the battery monitoring module after said computing device has not received a data input through the battery data input for a predetermined period of time.

13. The battery management system of claim 6, wherein the computing device is configured to shut off a battery charge when the computing device detects a high voltage condition across the first and second battery units.

14. The battery management system of claim 6, where in the battery management system comprises:
i. a first battery unit monitoring module coupled with a first battery unit and comprising:
an input data request port connected to the output data request port of the computing device; and
an output data request port;
an output data port connected to the input data port of the computing device; and
ii. a second battery unit monitoring module coupled with a second battery unit and comprising:
a single input data request port connected only to the output data request port of the first battery unit monitoring module, therein defining a module connection between said first battery unit monitoring module and said second battery unit monitoring module; and
wherein the first battery unit monitoring is a master to said second battery unit monitoring module and the second battery unit monitoring module is a slave to the first battery unit monitoring module;
wherein the first battery unit monitoring module responds to a data request signal from the output data request port of the computing device by transmitting data of the first battery unit to the input data port of the computing device and subsequently transmits a data request to the second battery unit monitoring module through said module connection; and
wherein the second battery unit monitoring module responds to the data request from the output data request port the first battery unit monitoring module by transmitting data of the second battery unit to first battery unit monitoring module for transmission to the input data port of the computing device;
wherein the computing device receives data from the first and second battery unit monitoring modules sequentially after sending a single data request signal to only the first battery unit monitoring module; and
wherein the computing device receives data from the second battery unit monitoring module automatically after receiving data from the first battery unit monitoring module.

15. A method of measuring the voltage of a plurality of batteries in a battery unit comprising the steps of:
a. providing a switched capacitor battery monitoring system comprising:
first switch capacitor battery monitor comprising:
a first capacitor coupled across the terminals of a first battery in a battery pack to produce a first capacitor voltage level that is substantially the same as a voltage level of said first battery; and
a first switch;
a second switch capacitor battery monitor comprising:
a second capacitor coupled across the terminals of a second battery in said battery pack to produce a second capacitor voltage level that is substantially the same voltage as a voltage level of said second battery; and
a second switch;
at least one analog-to-digital converter that is electrically coupled with the first and second switched capacitor battery monitors;
a single microprocessor;
b. isolating the first capacitor from the terminals of the first battery by opening the first switch chip to produce an isolated first capacitor;
c. electrically coupling the analog-to-digital converter to the isolated first capacitor,
d. converting the voltage level of the isolated first capacitor into a first digital signal;
c. isolating the second capacitor from the terminals of the second battery by opening the second switch chip to produce an isolated second capacitor;
f. electrically coupling the analog-to-digital converter to the isolated second capacitor and converting the voltage of the second capacitor into a second digital signal.

16. The method of claim 15, further comprising the step of transferring the first and second digital signals from the analog-to-digital converter to the microprocessor.

17. The method of claim 16, further comprising the step of transferring the first and second digital signals from the microprocessor to a computing device.
